(19) United States
(12) Patent Application Publication
(10) Pub. No.: US 2015/0348937 A1
(43) Pub. Date: Dec. 3, 2015

(54) SEMICONDUCTOR DEVICE AND METHOD FOR MANUFACTURING SAME

(71) Applicant: Kabushiki Kaisha Toshiba, Minato-ku (JP)

(72) Inventors: Yutaka ONOZUKA, Yokohama (JP); Hiroshi YAMADA, Yokohama (JP); Nobuto MANAGAKI, Kawasaki (JP)

(73) Assignee: Kabushiki Kaisha Toshiba, Minato-ku (JP)

(21) Appl. No.: 14/692,108

(22) Filed: Apr. 21, 2015

(30) Foreign Application Priority Data
Jun. 2, 2014 (JP) 2014-114223

(51) Int. Cl. H01L 25/065; H01L 23/00; H01L 23/31; H01L 21/768; H01L 21/288; H01L 23/48; H01L 23/538

(52) U.S. Cl. CPC H01L 25/0655; H01L 23/481; H01L 24/17; H01L 23/5386; H01L 21/76877; H01L 21/288; H01L 23/3107; H01L 2224/16113; H01L 2224/16265; H01L 2224/12105; H01L 2224/13025; H01L 2224/13111; H01L 2224/16055; H01L 2224/16057

(57) ABSTRACT

According to one embodiment, a semiconductor device includes an insulative resin, an interconnect, a plurality of semiconductor elements, and a first metal member. The insulative resin includes a first region and a second region. The interconnect is arranged with the first region in a first direction. The first direction intersects a direction from the first region toward the second region. The plurality of semiconductor elements is provided between the first region and the interconnect. At least one of the plurality of semiconductor elements is electrically connected to the interconnect. The first metal member includes a first through-portion and a first end portion. The first through-portion pierces the second region in the first direction. The first end portion is connected to the first through-portion. A width of the first end portion is wider than a width of the first through-portion in a second direction intersecting the first direction.

### CROSS-REFERENCE TO RELATED APPLICATIONS

This application is based upon and claims the benefit of priority from Japanese Patent Application No. 2014-114223, filed on Jun. 2, 2014; the entire contents of which are incorporated herein by reference.

### FIELD

Embodiments described herein relate generally to a semiconductor device and a method for manufacturing the same.

### BACKGROUND

Technology called pseudo SOC (System On Chip) has been proposed in which multiple semiconductor elements that are manufactured individually by different processes are disposed and reconfigured as a semiconductor device. It is desirable for the semiconductor device that uses pseudo SOC and the method for manufacturing the semiconductor device to have high reliability.

### BRIEF DESCRIPTION OF THE DRAWINGS

FIG. 1 is a cross-sectional view of a semiconductor device according to a first embodiment of the invention;

FIGS. 2A to 2F are cross-sectional views of processes, showing manufacturing processes of the semiconductor device according to the first embodiment;

FIG. 3 is a cross-sectional view of the semiconductor device according to the second embodiment of the invention;

FIGS. 4A to 4D are cross-sectional views of processes, showing manufacturing processes of the semiconductor device according to the second embodiment; and

FIG. 5 is a cross-sectional photograph of the first through-hole 111 vicinity after performing the process shown in FIG. 4B.

### DETAILED DESCRIPTION

According to one embodiment, a semiconductor device includes an insulative resin, an interconnect, a plurality of semiconductor elements, and a first metal member. The insulative resin includes a first region and a second region. The interconnect is arranged with the first region in a first direction. The first direction intersects a direction from the first region toward the second region. The plurality of semiconductor elements is provided between the first region and the interconnect. At least one of the plurality of semiconductor elements is electrically connected to the interconnect. The first metal member includes a first through-portion and a first end portion. The first through-portion pierces the second region in the first direction. The first end portion is connected to the first through-portion. A width of the first end portion is wider than a width of the first through-portion in a second direction. The second direction intersects the first direction.

Embodiments of the invention will now be described with reference to the drawings.

The drawings are schematic or conceptual; and the relationships between the thicknesses and widths of portions, the proportions of sizes between portions, etc., are not necessarily the same as the actual values thereof. Further, the dimensions and/or the proportions may be illustrated differently between the drawings, even in the case where the same portion is illustrated.

In the drawings and the specification of the application, components similar to those described in regard to a drawing thereinabove are marked with like reference numerals, and a detailed description is omitted as appropriate.

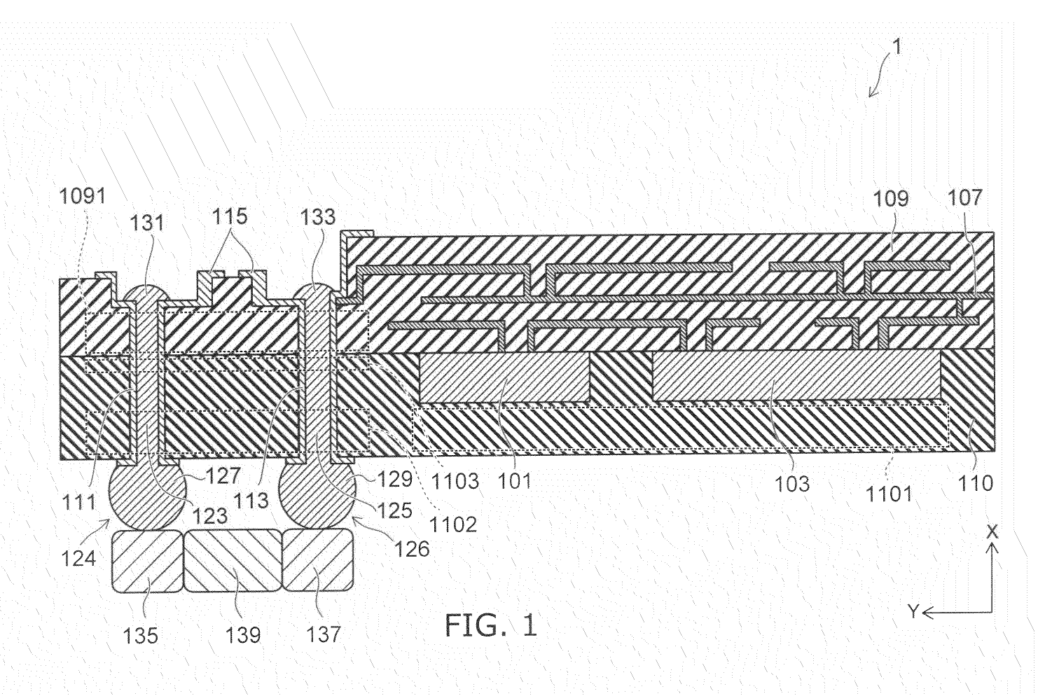

FIG. 1 is a cross-sectional view of a semiconductor device according to a first embodiment of the invention. The semiconductor device 1 includes an insulative resin 110, and a semiconductor element 101 and a semiconductor element 103 positioned inside the insulative resin 110. Semiconductor elements (e.g., LSI, etc.) that have various configurations and functions may be employed as the semiconductor elements 101 and 103. In the description hereinafter, the semiconductor elements 101 and 103 are called simply the “semiconductor elements” when not particularly differentiated.

An interconnect 107 and an organic insulating film 109 are disposed on the semiconductor elements and the insulative resin 110. The interconnect 107 is electrically connected to at least one of the semiconductor element 101 or 103.

The insulative resin 110 includes a first region 1101, a second region 1102, and a third region 1103. At least a portion of the interconnect 107 is arranged with at least a portion of the first region 1101 in a first direction D1 intersecting a direction from the first region 1101 toward the second region 1102. The first direction D1 is, for example, an X-direction shown in FIG. 1. The third region 1103 is arranged with the second region 1102 in the first direction D1.

The insulative resin 110 includes, for example, an epoxy resin. The organic insulating film 109 includes, for example, photosensitive polyimide. The interconnect 107 includes a conductive material, e.g., a stacked film of Al and Ti.

A first through-hole 111 and a second through-hole 113 are made in the insulative resin 110. The semiconductor device 1 further includes a first metal member 124 and a third metal member 126. The first metal member 124 includes a first through-portion 123 disposed inside the first through-hole 111 to pierce the second region 1102 and the third region 1103. The first metal member 124 further includes a first end portion 127 and a second end portion 131 connected to the first through-portion 123. Similarly, the third metal member 126 includes a third through-portion 125 disposed inside the second through-hole 113 to pierce the second region 1102 and the third region 1103. The third metal member 126 further includes a third end portion 129 and a fourth end portion 133 connected to the third through-portion 125.

The organic insulating film 109 includes a first insulating region 1091 arranged with the second region 1102 and the third region 1103 in the first direction D1. The first through-portion 123 pierces the first insulating region 1091. Similarly, the third through-portion 125 pierces the first insulating region 1091.

The inner wall of the first through-hole 111, the inner wall of the second through-hole 113, a portion of the insulative resin 110, and a portion of the organic insulating film 109 are covered with a metal film 115. A passive component 139 includes a first passive component electrode 135 and a second passive component electrode 137. The first passive component electrode 135 is connected to the first end portion 127; and the second passive component electrode 137 is connected to the third end portion 129. The metal film 115 includes, for example, copper. The first through-portion 123 and the third through-portion 125 include, for example, a solder material including tin. More specifically, for example, SnAgCu, SnCu, SnSb, etc., may be used as the solder material.

In the semiconductor device according to the embodiment, a material that is included in the first end portion 127 and the second end portion 131 is the same as a material that is included in the first through-portion 123; and the first end portion 127 and the second end portion 131 are continuous with the first through-portion 123. In other words, there is no boundary between the first end portion 127, the first through-portion 123, and the second end portion 131; and the first end portion 127, the first through-portion 123, and the second end portion 131 are formed as a single body.

Similarly for the third metal member 126, a material that is included in the third end portion 129 and the fourth end portion 133 is the same as a material that is included in the third through-portion 125; and the third end portion 129 and the fourth end portion 133 are continuous with the third through-portion 125. In other words, there is no boundary between the third end portion 129, the third through-portion 125, and the fourth end portion 133; and the third end portion 129, the third through-portion 125, and the fourth end portion 133 are formed as a single body.

Here, a direction intersecting the first direction D1 is taken as a second direction D2. The second direction D2 is, for example, a Y-direction shown in FIG. 1.

The first end portion 127 is formed so that the width of the first end portion 127 is wider than the width of the first through-portion 123 in the second direction D2. Also, the third end portion 129 is formed so that the width of the third end portion 129 is wider than the width of the third through-portion 125 in the second direction D2.

The width of the first metal member 124 may change from the width of the first through-portion 123 to the width of the first end portion 127 in a stairstep configuration in the first direction D1.

The width of the third metal member 126 may change from the width of the third through-portion 125 to the width of the third end portion 129 in a stairstep configuration in the first direction D1.

As an example, the first end portion 127 has a spherical configuration as shown in FIG. 1; and the diameter of the first end portion 127 is larger than the diameter of the first through-portion 123. As an example, the third end portion 129 also has a spherical configuration; and the diameter of the third end portion 129 is larger than the diameter of the third through-portion 125.

A method for manufacturing the semiconductor device according to the embodiment will now be described.

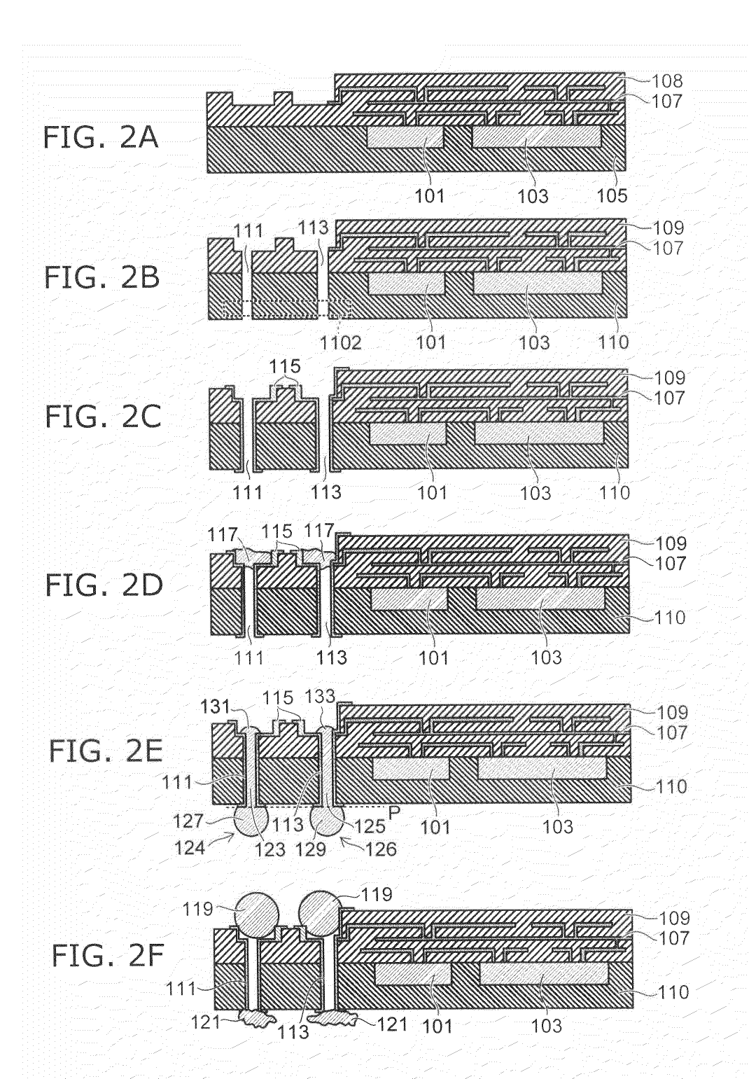

First, the semiconductor elements 101 and 103 are prepared; and the semiconductor elements are reconfigured using an insulative resin 105. Subsequently, an organic insulating film 108 and the interconnect 107 are formed on the insulative resin 105. The configuration at this time is shown in FIG. 2A.

Subsequently, the first through-hole 111 and the second through-hole 113 that extend in the first direction are made in the insulative resin 105 and the organic insulating film 108 by drilling. Thereby, the insulative resin 110 and the organic insulating film 109 that have the first through-hole 111 and the second through-hole 113 are made. The configuration at this time is shown in FIG. 2B.

Then, as shown in FIG. 2C, the metal film 115 that covers the inner wall of the first through-hole 111, the inner wall of the second through-hole 113, a portion of the insulative resin 110, and a portion of the organic insulating film 109 is formed by electroless plating. Although the metal film 115 is not essential in the embodiment, the metal film 115 is useful subsequently to cause a conductive material to flow easily when supplying the conductive material to the interior of the first through-hole 111 and the interior of the second through-hole 113.

Continuing as shown in FIG. 2D, solder paste 117 is coated onto the processing component in which the first through-hole 111 and the second through-hole 113 are made.

Subsequently, as shown in FIG. 2E, reflow of the solder paste 117 is performed. Thereby, a conductive material that has a liquid form is supplied to the first through-hole 111; one portion of the conductive material is positioned in the interior of the first through-hole 111; and one other portion of the conductive material is caused to flow out from the first through-hole 111. Then, by causing the conductive material to change into a solid form, the first through-portion 123 that is provided in the interior of the first through-hole 111 is formed from the one portion of the conductive material supplied to the first through-hole 111; and the first end portion 127 that is continuous with the first through-portion 123 is formed from the one other portion flowing out of the first through-hole 111.

Simultaneously, the conductive material that has the liquid form is supplied also to the second through-hole 113; one portion of the conductive material is positioned in the interior of the second through-hole 113; and one other portion of the conductive material is caused to flow out from the second through-hole 113. Then, by causing the conductive material to change into a solid form, the third through-portion 125 that is provided in the interior of the second through-hole 113 is formed from the one portion of the conductive material supplied to the second through-hole 113; and the third end portion 129 that is continuous with the third through-portion 125 is formed from the one other portion flowing out of the second through-hole 113.

At this time, the second end portion 131 that is continuous with the first through-portion 123 also is formed, and the fourth end portion 133 that is continuous with the third through-portion 125 also is formed.

Then, the semiconductor device shown in FIG. 1 is manufactured by connecting the passive component 139 by connecting the first passive component electrode 135 to the first end portion 127 and connecting the second passive component electrode 137 to the third end portion 129.

The process shown in FIG. 2F may be performed instead of the process shown in FIG. 2D described above. In the process shown in FIG. 2F, solder balls 119 are disposed on the first through-hole 111 and on the second through-hole 113; and flux 121 for oxidation prevention is coated onto the side opposite to the side where the solder balls 119 are disposed. After the process shown in FIG. 2F, similarly to the process of FIG. 2E, the first metal member 124 and the third metal member 126 are formed by performing reflow of the solder balls 119.

When performing the reflow of the solder in the process shown in FIG. 2E, the metal film 115 may be melted with the solder and may mix with the solder.

The formation process of the first end portion 127 will now be described in more detail. As shown in FIG. 2E, one portion of the conductive material remains in the interior of the first through-hole 111 after the conductive material having the liquid form is supplied to the first through-hole 111 interior; but one other portion of the conductive material flows outside the first through-hole 111 due to the weight of the one other portion. The conductive material that flows out at this time spreads in the second direction D2 outside the first through-hole 111 due to the surface tension with the insulative resin 110 or the metal film 115. As a result, the first end portion 127 is formed to spread in contact with the insulative resin 110 or the metal film 115 at a surface P which is the boundary between the first through-portion 123 and the first end portion 127. Also, the first end portion 127 is formed to have a width that is wider than the width of the first through-portion 123 in the second direction D2. The formation process of the third end portion 129 also is similar to the formation process of the first end portion 127.

The first end portion 127 having the width that is wider than the width of the first through-portion 123 is advantageous when mounting the semiconductor device 1 to the substrate on which the semiconductor device 1 is to be mounted because the gap between the semiconductor device 1 and the substrate can be increased and under-fill can be injected more easily to increase the bonding strength between the semiconductor device 1 and the substrate.

According to the embodiment, the adhesion between the first end portion 127 and the first through-portion 123 is improved; and peeling of the first end portion 127 from the semiconductor device 1 can be suppressed. As a result, operation errors of the semiconductor device are reduced; and it is possible to increase the reliability of the semiconductor device. Similarly for the third end portion 129 as well, peeling of the third end portion 129 from the semiconductor device 1 can be suppressed because the adhesion between the third end portion 129 and the third through-portion 125 is good.

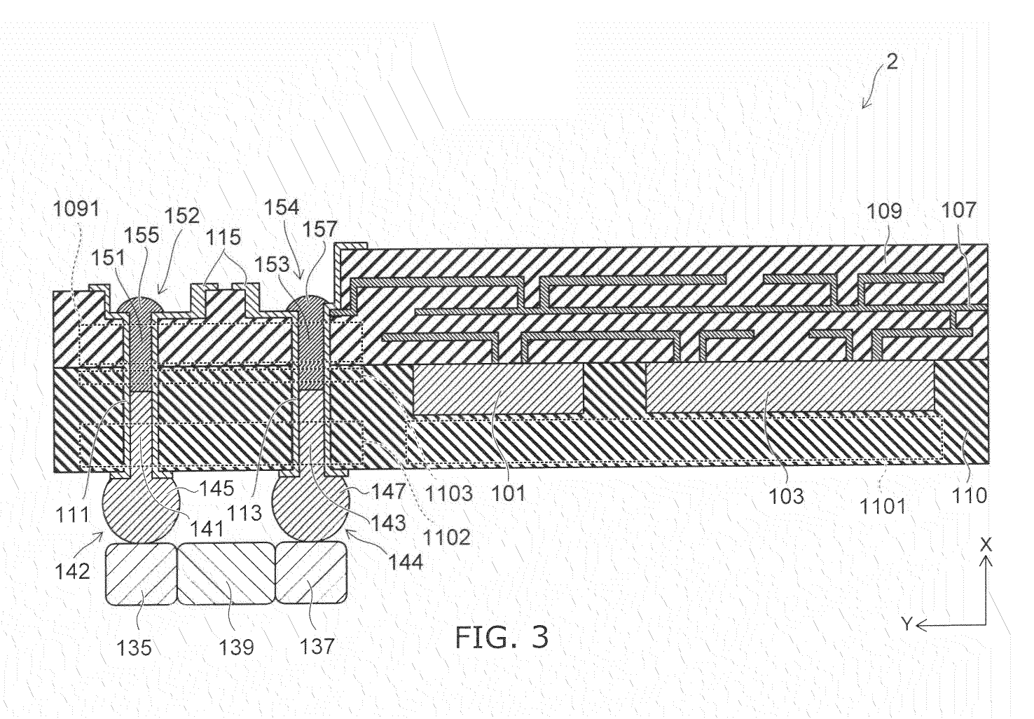

A semiconductor device according to a second embodiment of the invention and a method for manufacturing the semiconductor device according to the second embodiment will now be described with reference to FIG. 3 to FIG. 5.

FIG. 3 is a cross-sectional view of the semiconductor device according to the second embodiment of the invention. The semiconductor device 2 includes a first metal member 142, a second metal member 152, a third metal member 144, and a fourth metal member 154.

The first metal member 142 includes a first through-portion 141 piercing the second region 1102, and a first end portion 145 connected to the first through-portion 141. The second metal member 152 includes a second through-portion 151 piercing the third region 1103 and the first insulating region 1091, and a second end portion 155 connected to the second through-portion 151. The third metal member 144 includes a third through-portion 143 piercing the second region 1102, and a third end portion 147 connected to the third through-portion 143. The fourth metal member 154 includes a fourth through-portion 153 piercing the third region 1103 and the first insulating region 1091, and a fourth end portion 157 connected to the fourth through-portion 153.

A material that is included in the first end portion 145 is the same as a material that is included in the first through-portion 141. The first end portion 145 is continuous with the first through-portion 141; and there is no boundary between the first end portion 145 and the first through-portion 141. A material that is included in the second end portion 155 is the same as a material that is included in the second through-portion 151. The second end portion 155 is continuous with the second through-portion 151; and there is no boundary between the second end portion 155 and the second through-portion 151. The second through-portion 151 contacts the first through-portion 141 inside the first through-hole 111.

A material that is included in the third end portion 147 is the same as a material that is included in the third through-portion 143. The third end portion 147 is continuous with the third through-portion 143; and there is no boundary between the third end portion 147 and the third through-portion 143. A material that is included in the fourth end portion 157 is the same as a material that is included in the fourth through-portion 153. The fourth end portion 157 is continuous with the fourth through-portion 153; and there is no boundary between the fourth end portion 157 and the fourth through-portion 153. The fourth through-portion 153 contacts the third through-portion 143 inside the second through-hole 113.

The first end portion 145 is formed so that the width of the first end portion 145 is wider than the width of the first through-portion 141 in the second direction D2. The third end portion 147 also is formed so that the width of the third end portion 147 is wider than the width of the third through-portion 143 in the second direction D2.

The width of the first metal member 142 may change from the width of the first through-portion 141 to the width of the first end portion 145 in a stairstep configuration in the first direction D1.

The width of the third metal member 144 may change from the width of the third through-portion 143 to the width of the third end portion 147 in a stairstep configuration in the first direction D1.

A method for manufacturing the semiconductor device according to the embodiment will now be described.

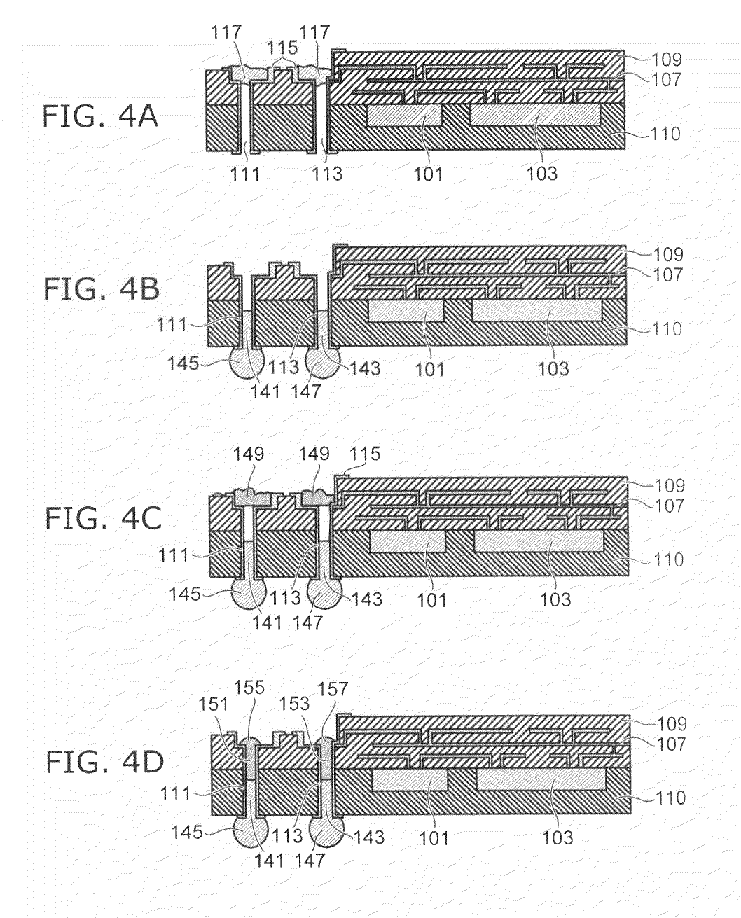

First, processes similar to the processes shown in FIGS. 2A to 2C are implemented to prepare a processing component in which the first through-hole 111 and the second through-hole 113 are made. Then, as shown in FIG. 4A, the solder paste 117 is coated onto the processing component.

Subsequently, as shown in FIG. 4B, reflow of the solder paste 117 is performed. A conductive material that has a liquid form is supplied to the first through-hole 111; one portion of the conductive material is positioned in the interior of the first through-hole 111; and one other portion of the conductive material is caused to flow out from the first through-hole 111. Then, by causing the conductive material to change into a solid form, the first through-portion 141 that is provided in the interior of the first through-hole 111 is formed from the one portion of the conductive material supplied to the first through-hole 111; and the first end portion 145 that is continuous with the first through-portion 141 is formed from the one other portion flowing out of the first through-hole 111.

Simultaneously, the conductive material that has the liquid form is supplied also to the second through-hole 113; one portion of the conductive material is positioned in the interior of the second through-hole 113; and one other portion of the conductive material is caused to flow out from the second through-hole 113. Then, by causing the conductive material to change into a solid form, the third through-portion 143 that is provided in the interior of the second through-hole 113 is formed from the one portion of the conductive material supplied to the second through-hole 113; and the third end portion 147 that is continuous with the third through-portion 143 is formed from the one other portion flowing out of the second through-hole 113.

At this time, the first through-portion 141 and the third through-portion 143 are formed so that the first through-portion 141 and the third through-portion 143 pierce the second region 1102.

Then, solder paste 149 is coated as shown in FIG. 4C.

Continuing as shown in FIG. 4D, reflow of the solder paste 149 is performed. By supplying a conductive material that has a liquid form to the interior of the first through-hole 111, the second through-portion 151 that pierces the third region 1103 and the first insulating region 1091 is formed; and the second end portion 155 is formed. Similarly, by supplying the conductive material that has the liquid form to the interior of the second through-hole 113, the fourth through-portion 153 that pierces the third region 1103 and the first insulating region 1091 is formed; and the fourth end portion 157 is formed.

Subsequently, the semiconductor device shown in FIG. 3 is manufactured by connecting the passive component 139 by connecting the first passive component electrode 135 to the first end portion 145 and connecting the second passive component electrode 137 to the third end portion 147.

In the embodiment, the first metal member 142 and the second metal member 152 are formed so that the first through-portion 141 pierces the second region 1102 and the second through-portion 151 pierces the third region 1103. However, the embodiment is not limited to such a form; and the first metal member 142 and the second metal member 152 may be formed so that the first through-portion 141 pierces the second region 1102 and the third region 1103 and the second through-portion 151 pierces the first insulating region 1091.

A material that has a lower melting point than the solder paste 117 is used as the material of the solder paste 149. Thereby, melting of the first metal member 142 and the third metal member 144 formed of the solder paste 117 can be suppressed when performing reflow of the solder paste 149 to form the second metal member 152 and the fourth metal member 154. The solder paste 117 and the solder paste 149 may include a material including tin. More specifically, for example, SnCu or SnSb may be used as the material of the solder paste 117; and SnAgCu which has a lower melting point than SnCu and SnSb may be used as the material of the solder paste 149.

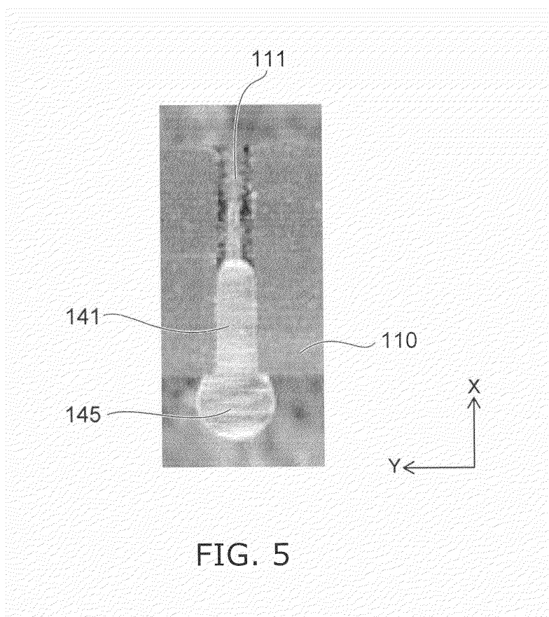

FIG. 5 is a cross-sectional photograph of the first through-hole 111 vicinity after performing the process shown in FIG. 4B. It can be seen from FIG. 5 that the first through-portion 141 that is formed in the first through-hole 111 interior is formed to be continuous with the first end portion 145. Further, it can be seen that there is no boundary between the first through-portion 141 and the first end portion 145; and the first through-portion 141 and the first end portion 145 are formed as a single body.

It can be seen that the width of the first end portion 145 is wider than the width of the first through-portion 141 in the second direction D2. Further, it can be seen that the first end portion 145 spreads in the in-plane direction of the insulative resin 110 on the surface of the insulative resin 110.

According to the embodiment, the adhesion between the first end portion 145 and the first through-portion 141 is improved; and the peeling of the first end portion 145 from the semiconductor device 2 can be suppressed. As a result, the operation errors of the semiconductor device are reduced; and it is possible to increase the reliability of the semiconductor device. Similarly, the adhesion between the second end portion 155 and the second through-portion 151, the adhesion between the third end portion 147 and the third through-portion 143, and the adhesion between the fourth end portion 157 and the fourth through-portion 153 are improved; and the peeling of these end portions from the semiconductor device 2 can be suppressed.

Expectations are high for compact electronic devices having wireless communication functions typified by mobile telephones, personal digital assistants (PDAs), etc., as society approaches a ubiquitous computing society. Therefore, smaller and lighter electronic devices are being developed. Even more functions and higher performance will continue to be necessary to respond to increasingly diverse needs. The integration of high frequency devices is essential for wireless communication devices. To satisfy these needs, devices having different capabilities are integrated because there is a limit to the performance improvement of a single device. However, it is difficult to form a device having the function of a passive component on an LSI chip. The integration density is low for methods for integrating an LSI chip and a passive component on a substrate. Therefore, technology is desirable to realize high-density integration of heterogeneous devices such as combinations of passive components and LSI chips on one chip.

A first method for integrating heterogeneous devices is called system on chip (SOC). In this method, multiple devices are integrated by all of them being formed directly on one chip. In this method, the integration of the devices is high; and it is possible to downscale the global interconnects between the devices because the global interconnects are formed on the one chip. Therefore, higher integration, higher performance, and a thinner package are possible. However, there is a limit to how much devices can be integrated. For example, it is difficult to form a device based on a different crystal system such as GaAs, etc., on a Si substrate due to differences of the lattice constants and differences of the coefficients of thermal expansion. It is inefficient to use the same processes to make devices requiring high definition design rules such as LSI, etc., and devices formed using low definition design rules. In particular, when embedding a new device, the cost of development is high and the development time is long for the new device because all of the processes are modified.

A second method is called system in package (SIP). In this method, multiple chips are formed separately, subdivided, and mounted on a substrate called an interposer. In this method, there are few limitations on the devices because each of devices can be formed individually. In this method, the development cost can be low and the development time can be short because it is possible to utilize existing chips when developing new systems. However, a density increase of the chip arrangement, downscaling of the interconnects, and a thinner package are difficult to realize because the connections between the interposer and the chips are performed by bonding wires, bumps, etc.

On the other hand, the following method is used in a first reference example. Multiple heterogeneous devices that are formed by each type of manufacturing technology are tested, sorted, and subsequently formed as a reconfiguration wafer using a resin. Further, insulating layers and interconnect layers are formed using semiconductor processes; singulation is performed by dicing; and the modules are completed. In the first reference example, unlike SIP, an interposer is not used. Also, the connections between the devices are performed by interconnects made by semiconductor processes. Thereby, higher integration is possible. In the first reference example, unlike SOC, it is possible to provide heterogeneous devices together. Accordingly, when configuring new systems, it is considered that existing devices can be used; the development time is reduced; and as a result, the development cost can be reduced.

Also, there is the following second reference example. An interconnect layer is formed on a resin wafer; and subsequently, through-vias are formed by making through-holes in the interconnect layer and the resin wafer and by filling the through-holes with a metal. Subsequently, a barrier metal and solder balls are formed on one or both sides of the resin wafer. Thereby, the substrate mounting of the modules is performed; and three-dimensional stacking is possible. Stress fractures that occur in the resin portions fixing the heterogeneous devices are suppressed by forming the solder balls on the resin portion; and the connection reliability of the modules is increased.

However, in the second reference example, it was found that the adhesion between the barrier metal and the organic insulating film which is the foundation is weak; and connection defects occur due to peeling of the barrier metal when forming the solder balls.

According to the embodiments described above, a semiconductor device can be provided in which it is possible to suppress peeling of the solder balls positioned on the side of the insulative resin where the interconnects are disposed. Then, according to the embodiments, a semiconductor device having high reliability is provided.

Hereinabove, embodiments of the invention are described with reference to specific examples. However, the invention is not limited to these specific examples. For example, one skilled in the art may similarly practice the invention by appropriately selecting specific configurations of components such as the insulative resin, the semiconductor element, the organic insulating film, the interconnect, the through-portion, the electrode, the end portion, etc., from known art; and such practice is within the scope of the invention to the extent that similar effects can be obtained.

Further, any two or more components of the specific examples may be combined within the extent of technical feasibility and are included in the scope of the invention to the extent that the purport of the invention is included.

Moreover, all semiconductor devices and all methods for manufacturing the same practicable by an appropriate design modification by one skilled in the art based on the semiconductor devices and the methods for manufacturing the same described above as embodiments of the invention also are within the scope of the invention to the extent that the spirit of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device, comprising:
an insulative resin including a first region and a second region;
an interconnect arranged with the first region in a first direction intersecting a direction from the first region toward the second region;
a plurality of semiconductor elements provided between the first region and the interconnect, at least one of the plurality of semiconductor elements being electrically connected to the interconnect; and
a first metal member including a first through-portion and a first end portion, the first through-portion piercing the second region in the first direction, the first end portion being connected to the first through-portion,
a width of the first end portion being wider than a width of the first through-portion in a second direction intersecting the first direction.

2. The device according to claim 1, wherein
the first end portion is continuous with the first through-portion, and
a material included in the first through-portion is the same as a material included in the first end portion.

3. The device according to claim 1, wherein a width of the first metal member in the second direction changes from the width of the first through-portion to the width of the first end portion in a stairstep configuration in the first direction.

4. The device according to claim 1, further comprising an organic insulating film including a first insulating region,
the first insulating region being arranged with the second region in the first direction,
the first through-portion piercing the first insulating region.

5. The device according to claim 1, further comprising an organic insulating film and a second metal member, the organic insulating film including a first insulating region,
the first insulating region being arranged with the second region in the first direction,
the second metal member including a second through-portion and a second end portion, the second through-portion piercing the first insulating region in the first direction, the second end portion being connected to the second through-portion.

6. The device according to claim 5, wherein the second through-portion contacts the first through-portion.

7. The device according to claim 5, wherein
the insulative resin includes a third region arranged with the second region in the first direction, and
the second through-portion pierces the third region.

8. The device according to claim 5, wherein
the second end portion is continuous with the second through-portion, and
a material included in the second through-portion is the same as a material included in the second end portion.

9. The device according to claim 5, wherein a melting point of a material included in the second through-portion and the second end portion is lower than a melting point of a material included in the first through-portion and the first end portion.

10. The device according to claim 5, wherein the second through-portion and the second end portion include tin.

11. The device according to claim 1, wherein the first through-portion and the first end portion include tin.

12. The device according to claim 1, wherein the first end portion is electrically connected to the interconnect.

13. The device according to claim 1, further comprising a third metal member including a third through-portion and a third end portion, the third through-portion piercing the second region in the first direction, the third end portion being connected to the third through-portion,
a width of the third end portion being wider than a width of the third through-portion in the second direction.

14. The device according to claim 13, wherein
the third end portion is continuous with the third through-portion, and
a material included in the third through-portion is the same as a material included in the third end portion.

15. The device according to claim 13, wherein a material included in the first metal member is the same as a material included in the third metal member.

16. The device according to claim 13, further comprising a passive component including a first passive component electrode and a second passive component electrode,
the first passive component electrode being connected to the first end portion,
the second passive component electrode being connected to the third end portion.

17. The device according to claim 13, further comprising a fourth metal member,
the fourth metal member including a fourth through-portion and a fourth end portion, the fourth through-portion piercing the third region in the first direction, the fourth end portion being connected to the fourth through-portion.

18. The device according to claim 17, wherein the fourth through-portion contacts the third through-portion.

19. The device according to claim 1, wherein
the first end portion has a spherical configuration, and
a diameter of the first end portion is larger than a diameter of the first through-portion.

20. A method for manufacturing a semiconductor device, comprising:
preparing a processing component including an insulative resin and a plurality of semiconductor elements, a through-hole being provided in the insulative resin to extend in a first direction;
supplying a conductive material having a liquid form to the through-hole, causing one portion of the conductive material to be positioned in an interior of the through-hole, and causing one other portion of the conductive material to flow out from the through-hole; and
causing the conductive material to change into a solid form to form, from the one portion, a through-portion provided in the interior of the through-hole and form, from the one other portion, an end portion continuous with the through-portion,
a width of the end portion being wider than a width of the through-portion in a second direction intersecting the first direction.
